(19) United States
(12) Patent Application Publication
(10) Pub. No.: US 2015/0357494 A1
(43) Pub. Date: Dec. 10, 2015

(54) GAS PERMEATION BARRIER MATERIAL AND ELECTRONIC DEVICES CONSTRUCTED THEREWITH

(71) Applicant: E . I . DU PONT DE NEMOURS AND COMPANY, Wilmington, DE (US)

(72) Inventors: David M. Dean, West Chester, PA (US); Carl Brent Douglas, Boothwyn, PA (US); Nicholas J. Glassmaker, Wilmington, DE (US)

(21) Appl. No.: 14/763,734

(22) PCT Filed: Jan. 30, 2014
(86) PCT No.: PCT/US2014/013763

§ 371 Date: Jul. 27, 2015

Related U.S. Application Data
(60) Provisional application No. 61/758,859, filed on Jan. 31, 2013.

(51) Int. Cl. H01L 31/048; H01L 51/52; H01L 31/18; H01L 51/56

(52) U.S. Cl. CPC H01L 31/0481; H01L 51/56; H01L 51/5253; H01L 31/18

(57) ABSTRACT

A gas permeation barrier structure comprises a rigid or flexible substrate, an oxide or nitride layer deposited thereon by atomic layer deposition (ALD), and a polymeric clear coat. The presence of the polymeric clear coat permits the barrier structure to maintain resistance to permeation of gases including oxygen and water vapor longer than would a structure in which the ALD layer is directly exposed to atmosphere.

### CROSS REFERENCE TO RELATED APPLICATION

The present application claims benefit of U.S. Provisional Patent Application Ser. No. 61/758,859, filed Jan. 31, 2013, which is incorporated herein in the entirety for all purposes.

### FIELD OF THE INVENTION

The present invention relates to a moisture barrier and electronic devices constructed therewith, and more particularly to a moisture barrier comprising a gas-impermeable inorganic layer prepared by atomic layer deposition and a top layer comprising a protective coating, such as an isocyanate- or melamine-cured acrylic protective coating.

### TECHNICAL BACKGROUND OF THE INVENTION

A wide variety of industrial and commercial products and devices require some level of protection from ambient oxygen and/or water vapor to prevent degradation or failure. Some items can readily be sealed within a rigid, possibly metallic, hermetic structure, but for other items, a flexible protective structure is desired or required. For example, certain types of low-cost polymer films afford adequate short-term protection for foodstuffs and other consumer goods, notwithstanding the relatively facile permeation of oxygen and water vapor through them. It is generally believed that typical polymers have an inherently high free volume fraction that provides diffusion pathways that give rise to the observed level of permeability. A thin metallization can give a substantial improvement, but makes the polymer film opaque. Aluminum-coated polyester is one such material in common use.

However, optical transparency is desirable or essential for some applications. For example, polymers with an optically transparent, inorganic barrier layer are used in some food, beverage, and pharmaceutical packaging. Barrier materials such as SiOₓ and AlO_{y} can be applied either by physical vapor deposition (PVD) or chemical vapor deposition (CVD), producing materials known in the industry as “glass-coated” barrier films. They provide an improvement for atmospheric gas permeation of about 10×, reducing transmission rates to about 1.0 cc O₂/m²/day and 1.0 ml H₂O/m²/day through polyester film (M. Izu, B. Dotter, and S. R. Ovshinsky, J. Photopolymer Science and Technology., vol. 8, 1995, pp. 195-204). While this modest improvement is a reasonable compromise between better properties and cost for many high-volume packaging applications, the protection afforded still falls far short of the far more challenging requirements for many electronic devices. Packaging of consumer goods is typically required only to maintain the items in suitable condition through manufacturing and distribution and for a defined, relatively short shelf life thereafter. On the other hand, electronic articles must operate satisfactorily over the entire useful life of the product, which is often an order of magnitude longer or more.

Many common electronic devices use materials that react with water and/or oxygen; exposure to these contaminants can unacceptably degrade device performance. Thus, a durable improvement in resistance to gas permeation by a factor of 10⁴-10⁶ may be required. While known inorganic coatings provide some reduction of the permeability, the levels typically attained are still inadequate. Both microstructural features and larger-scale defects are believed to contribute.

Ideally, a thin-film coating, e.g., one employing an inorganic material, that is both continuous and free from such defects should be adequate. However, the practical reality is that even elimination of obvious macroscopic defects such as pinholes that arise either from the coating process or from substrate imperfections, is still not enough to provide protection sufficient to maintain the desired device performance in practical devices.

For example, it is known that even microscopic cracks in a coating compromise its protective ability, providing a facile pathway for ambient gases to intrude. Such cracks can arise either during coating formation or thereafter.

CVD and PVD and other deposition methods commonly used to deposit inorganic materials generally entail initiation and film growth at discrete nucleation sites. The resulting materials ordinarily have microstructural features that create pathways that allow gas permeation. PVD methods are known to be particularly prone to creation of columnar microstructures having grain boundaries and other comparable defects, along which gas permeation can be especially facile.

Display devices based on organic light emitting polymers (OLEDs) exemplify the need for exacting protection, e.g., a barrier improvement of ˜10⁵-10⁶× over what is attainable with present flexible barrier materials having a PVD or CVD coating. Both the light-emitting polymer and the cathode (typically made with Ca or Ba metal) are water-sensitive. Without adequate protection, device performance may degrade rapidly.

Photovoltaic (PV) cells provide another example. To capture sunlight, these devices are necessarily mounted in outdoor locations exposed to harsh conditions of temperature and moisture, including precipitating snow and rain. To be economically viable, a long usable lifetime, e.g., at least 25 years, is presumed for PV installations.

PV cells based on thin-film technologies such as amorphous silicon (a-Si), cadmium telluride (CdTe), copper indium (gallium) di-selenide/sulfide (CIS/CIGS), and dye-sensitized, organic and nano-materials are of great current interest, because of their potential to provide high efficiency conversion. Moisture sensitivity is an issue for all these technologies, but is particularly acute for CIGS-based PV cells. In different embodiments, a CIGS-based cell needs a barrier with a water vapor transmission rate less than 5×10⁻⁴ g-H₂O/m² day or less than 4×10⁻⁵ g-H₂O/m² day to have a viable lifetime of 20-25 years. Despite this stringent requirement, PV cells based on CIGS and related materials are attractive because of the high efficiency (˜20%) they have exhibited in small laboratory-size experiments under controlled conditions.

Thus, there remains a need for flexible substrates, protective structures, and barrier materials, particularly ones that meet the needs for constructing and packaging electronic devices, including thin-film PV cells, OLEDs, and the like.

### SUMMARY OF THE INVENTION

An embodiment of the invention relates to a barrier structure, comprising, in sequence:
(a) a carrier substrate;
(b) an inorganic layer deposited on the carrier substrate and comprising an oxide or a nitride of an element selected from Groups IVB, VB, VIB, IIIA, IVA of the periodic table, the oxide or nitride having an amorphous and featureless microstructure; and
(c) a polymeric layer adhered to the inorganic layer and comprising a network wherein units of a crosslinkable component are linked to units of a crosslinking component, and at least one of the crosslinkable component and the crosslinking component includes isocyanate functionality.

Another aspect provides an electronic device, comprising:
(a) a circuit element;
(b) a barrier coating comprising an inorganic layer and a polymeric layer disposed, in sequence, on the circuit element, and wherein:
   (i) the inorganic layer comprises an oxide or a nitride of an element selected from Groups IVB, VB, VIB, IIIA, IVA of the periodic table, the oxide or nitride having an amorphous and featureless microstructure; and
   (ii) the polymeric layer thereon comprises a network wherein units of a crosslinkable component are linked to units of a crosslinking component, at least one of the crosslinkable component and the crosslinking component including isocyanate functionality.

Still another aspect provides a process for manufacturing a barrier coating comprising the steps of:
(a) providing a substrate having a major surface;
(b) depositing an inorganic layer on the substrate using an atomic layer deposition process, the inorganic layer comprising an oxide or a nitride of an element selected from Groups IVB, VB, VIB, IIIA, IVA of the periodic table, the oxide or nitride having an amorphous and featureless microstructure;
(c) thereafter applying on the inorganic layer a polymeric layer that comprises a network wherein units of a crosslinkable component are linked to units of a crosslinking component, at least one of the crosslinkable component and the crosslinking component including isocyanate functionality.

### BRIEF DESCRIPTION OF THE DRAWINGS

The invention will be more fully understood and further advantages will become apparent when reference is made to the following detailed description of the preferred embodiments and the accompanying drawings, wherein like reference numerals denote similar elements throughout the several views and in which:

FIG. 1 depicts a test structure useful in characterizing the gas permeability of a barrier structure of the invention; and

FIG. 2 is a plot showing the change in permeation of water vapor through a barrier structure of the invention and a comparison structure as a function of exposure to damp heat, as signaled by a change in the color of moisture-sensitive test strips.

### DETAILED DESCRIPTION OF THE INVENTION

As used herein:

The term “atomic layer deposition” (ALD) refers to a method for growing a film on a substrate in an atomic layer-by-layer sequence carried out repetitively, whereby the film having the requisite thickness is formed. The process is carried out using a reaction that has at least two, and possibly more, stages. At each stage, a precursor substance is deposited. The sequential precursors react to form the requisite composition. A description of some exemplary ALD processes can be found in “Atomic Layer Epitaxy,” by Tuomo Suntola, Thin Solid Films, vol. 216 (1992) pp. 84-89.

The terms “(meth)acrylate” and “(meth)acrylic respectively refer to either methacrylate or acrylate and to either methacrylic or acrylic.

The term “one-pack coating composition,” also known as a “1K coating composition,” refers to a coating composition that can be stored in one package and remain useful for a certain shelf life. For example, a one-pack coating composition can be a UV mono-cure coating composition that can be prepared to form a pot mix and stored in a sealed container. As long as the UV mono-cure coating composition is not exposed to UV radiation, it can have indefinite pot life. Other examples of one-pack coating compositions can include ones having blocked crosslinking agent such as blocked isocyanates, moisture curing one-pack coating compositions, oxygen curing one-pack coating compositions, or heat curing one-pack coating compositions as known in coating industry.

The term “two-pack coating composition,” also known as a “2K coating composition,” refers to a coating composition having two packages that are stored in separate containers and sealed to increase the shelf life of the coating composition during storage. Typically, the two packages are mixed just prior to use to form a pot mix, which may have a limited pot life, typically ranging from a few minutes (15 minutes to 45 minutes) to a few hours (4 hours to 8 hours). The pot mix is then applied as a layer of a desired thickness on a substrate surface, such as a photovoltaic cell or other optoelectronic device as provided herein. After application, the layer dries and cures at ambient or at elevated temperatures to form a polymeric coating on the substrate surface having desired coating properties, such as adhesion and resistance to abrasion and moisture penetration.

The term “crosslinkable component” refers to a component having “crosslinkable functional groups” that are functional groups positioned in each molecule of a compound, oligomer, polymer, a backbone of a polymer, pendant from a backbone of a polymer, terminally positioned on a backbone of a polymer, or a combination thereof. These functional groups are capable of crosslinking with crosslinking functional groups during a curing step to produce a polymeric coating having crosslinked structures. One of ordinary skill in the art would recognize that certain crosslinkable functional group combinations would be excluded, since, if present, these combinations would crosslink among themselves (self-crosslink), thereby precluding their ability to crosslink with the crosslinking functional groups. A workable combination of crosslinkable functional groups refers to a combination of crosslinkable functional groups that can be used in coating applications, and excludes those combinations that would self-crosslink.

Typical crosslinkable functional groups include, without limitation, hydroxyl, thiol, isocyanate, thioisocyanate, acetoacetoxy, carboxyl, primary amine, secondary amine, epoxy, anhydride, ketimine, or aldimine groups, or a workable combination thereof. Some other functional groups such as orthoester, orthocarbonate, or cyclic amide that can generate hydroxyl or amine groups once the ring structure is opened can also be suitable as crosslinkable functional groups.

The term “crosslinking component” refers to a component having “crosslinking functional groups,” which are functional groups positioned in each molecule of a compound, oligomer, polymer, a backbone of a polymer, pendant from a backbone of a polymer, terminally positioned on a backbone of a polymer, or a combination thereof. These functional groups are capable of crosslinking with the crosslinkable functional groups during a curing step to produce a polymeric coating having crosslinked structures. One of ordinary skill in the art would recognize that certain crosslinking functional group combinations would be excluded, since, if present, these combinations would crosslink among themselves (self-crosslink), thereby destroying their ability to crosslink with the crosslinkable functional groups. A workable combination of crosslinking functional groups refers to a combination of crosslinking functional groups that can be used in coating applications, and excludes those combinations that would self-crosslink. One of ordinary skill in the art would recognize that certain combinations of crosslinking functional group and crosslinkable functional groups would be excluded, since they would fail to crosslink and produce film-forming, crosslinked structures. The crosslinking component can comprise one or more crosslinking agents that have crosslinking functional groups.

Typical crosslinking functional groups include, without limitation, hydroxyl, thiol, isocyanate, thioisocyanate, acetoacetoxy, carboxyl, primary amine, secondary amine, epoxy, anhydride, ketimine, aldimine, orthoester, orthocarbonate, or cyclic amide groups, or a workable combination thereof.

It would be clear to one of ordinary skill in the art that certain crosslinking functional groups are adapted to crosslink with certain crosslinkable functional groups. Examples of paired combinations of crosslinkable and crosslinking functional groups include, without limitation: (1) amine and protected amine such as ketimine and aldimine functional groups that generally crosslink with acetoacetoxy, epoxy, or anhydride functional groups; (2) isocyanate, thioisocyanate and melamine functional groups that generally crosslink with hydroxyl, thiol, primary and secondary amine, ketimine, or aldimine functional groups; (3) epoxy functional groups that generally crosslink with carboxyl, primary and secondary amine, ketimine, aldimine or anhydride functional groups; and (4) carboxyl functional groups that generally crosslink with epoxy or isocyanate functional groups.

While any of these chemistries can produce a coating that would contribute to the physical properties of a composite barrier coating, it would also be clear to one of ordinary skill in the art that certain chemistries would be more readily applicable to the goals of a high degree of transparency, resistance to a wide range of atmospheric conditions, and long term durability. In an embodiment, a one-pack (meth)acrylate coating composition cured using UV or e-beam radiation may be employed. In other embodiments, two-pack coating compositions are useful, For example, thermally cured, isocyanate-hydroxyl or melamine-hydroxyl based compositions may be employed. In general, isocyanate-hydroxyl based compositions permit use of a relatively low curing temperature, minimizing any tendency for stresses to arise from thermal mismatch, while melamine-hydroxyl based compositions are generally very durable.

Depending upon the type of crosslinking agent, the polymeric coating composition useful in the practice of the present disclosure can be formulated as a one-pack or aq two-pack coating composition. If polyisocyanates with reactive isocyanate or melamine groups are used as the crosslinking agent, the polymeric coating composition can be formulated as a two-pack coating composition wherein the crosslinking agent is mixed with other components of the coating composition only shortly before coating application. If blocked polyisocyanates are, for example, used as the crosslinking agent, the polymeric coating composition can be formulated as a one-pack coating composition. As understood by those skilled in the art, the viscosity of the polymeric coating composition can be further adjusted with one or more organic solvents to be appropriate for a desired application method.

The term “binder” as used herein refers to the film forming constituents of a polymeric coating composition. Typically, a binder can comprise a crosslinkable component and a crosslinking component adapted to react to form a crosslinked structure, such as a coating film. The binder in the polymeric coating composition useful in practicing the present disclosure can further comprise other polymers, compounds or molecules that are beneficial in forming crosslinked coatings having desired properties, such as good adhesion. Additional components, such as solvents, catalysts, rheology modifiers, antioxidants, UV stabilizers and absorbers, leveling agents, antifoaming agents, anti-cratering agents, or other conventional additives are not included in the term. One or more of those additional components can be included in the polymeric coating composition used herein.

In one aspect, the present disclosure provides a barrier material comprising an inorganic material formed by atomic layer deposition (ALD) that is further protected by an acrylic polymer layer. In some embodiments, such a barrier provides robust and durable protection against permeation of atmospheric gases such as oxygen and water vapor. The barrier material may be disposed on a substrate, which in turn may be used to seal a circuit device or other object for which protection against gas and/or water vapor intrusion is sought, e.g. by lamination or adhesive bonding. Alternatively, the barrier material, with the polymeric coating, may be deposited directly onto a circuit device, possibly with an intervening thin adhesion layer.

The barrier structure is usefully employed in constructing a variety of devices for which protection is sought. In general, the substrate may comprise metal, polymer, or glass, and may be either rigid or flexible. Thin metal and polymer substrates have the advantage of being flexible; glass and some polymers have the advantage of being transparent or translucent. Suitable carrier substrates include both glasses and the general class of polymeric materials, such as described by but not limited to those in Polymer Materials, (Wiley, New York, 1989) by Christopher Hall or Polymer Permeability, (Elsevier, London, 1985) by J. Comyn. Common examples include polyesters such as polyethylene terephthalate (PET) and polyethylene naphthalate (PEN), polyamides, polyacrylates, polyimides, polycarbonates, polyarylates, polyethersulfones, polycyclic olefins, fluoropolymers such as polytetrafluoroethylene (PTFE), polyvinyl fluoride (PVF), perfluoroalkoxy copolymer (PFA), or fluorinated ethylene propylene (FEP), and the like. Both flexible and rigid forms of these polymers may be used. Many flexible polymer materials are commercially available as film base by the roll, and may be suitable for encapsulating devices, such as thin-film photovoltaic devices, organic light-emitting diode devices, and the like. Thus, barrier structures formed by depositing barrier coatings on any of the foregoing substrates may be either rigid or flexible. In some embodiments, the barrier layers resist formation of cracks or like defects during flexure, so that the layers retain a high resistance to gas permeation. In addition to the barrier coating provided herein, the substrate may also include other functional coatings used to enhance other optical, electrical, or mechanical properties that are beneficial in an end-use application.

In another representative aspect, an electronic or other device can be protected either by applying the barrier coating directly to it or by depositing the barrier coating on a rigid or flexible substrate material that is sealed to the device.

As noted above, the ALD process can be used to form a film by repeatedly depositing atoms of the requisite material in a layer-by-layer sequence. The ALD process is frequently accomplished in a chamber using a two-stage reaction, but other configurations can also be used, including, without limitation, in-line processes such as those disclosed in US Patent Publication No. 2011/0023775 to Nunes et al., which is incorporated herein in its entirety for all purposes by reference thereto.

For example, the atomic layer deposition process used in constructing the present barrier structure may be carried out in a reaction zone and comprise carrying out a plurality of deposition cycles, wherein each deposition cycle comprises in sequence the steps of:
(a) admitting into the reaction zone a first reactant precursor vapor capable of forming an adsorbed layer on the major surface of the substrate;
(b) purging the reaction zone to remove any unadsorbed first reactant precursor vapor and any volatile reactants and reaction products produced in step (a);
(c) admitting into the reaction zone a second reactant precursor vapor; and
(d) purging the reaction zone to remove any unadsorbed second reactant precursor vapor and any volatile reactants and reaction products produced in step (c),
wherein the steps (a)-(c) are carried out under thermal conditions that promote a reaction of the first reactant precursor vapor and second reactant precursor vapor to form the oxide or nitride.

In one exemplary embodiment, a vapor of film precursor is introduced into a chamber or other reaction zone. Without being bound by any theory, it is believed that a thin layer of the precursor, usually essentially a monolayer, is adsorbed on a substrate or device in the chamber. As used herein, the term “adsorbed layer” is understood to mean a layer whose atoms are chemically bound to the surface of a substrate. Thereafter, any remaining vapor and volatile reaction products are purged from the chamber or zone, e.g., by evacuating the chamber or by flowing an inert purging gas, to remove any excess or unadsorbed vapor. A reactant is then introduced into the chamber or zone. The process steps are carried out under thermal conditions that promote a chemical reaction between the reactant and the precursor to form a sublayer of the desired barrier material. The volatile reaction products and excess precursors are then purged. Additional sublayers of material are formed by repeating the foregoing steps for a number of times sufficient to form a layer having a preselected thickness.

Alternatively, in some in-line processes, the deposition and purging steps are carried out by translating the substrate to bring it into different stations, in which the required process steps of the deposition are accomplished in a sequence defined by the motion of the substrate.

Although capable of producing films of a number of types, ALD is most commonly used to deposit inorganic oxides and nitrides, such as aluminum, silicon, zinc, or zirconium oxide and silicon or aluminum nitride. In some instances, the oxides and nitrides produced by ALD may deviate slightly from the stoichiometry of the corresponding bulk material, but still provide the necessary functionality for a gas permeation barrier coating.

Materials formed by ALD that are suitable for barriers include, without limitation, oxides and nitrides of elements of Groups IVB, VB, VIB, IIIA, and IVA of the Periodic Table and combinations thereof. Particular examples of these materials include Al₂O₃, SiO₂, TiO₂, ZrO₂, HfO₂, MoO₃, SnO₂, In₂O₃, Ta₂O₅, Nb₂O₅, SiNₓ, and AlNₓ. Of particular interest in this group are SiO₂, Al₂O₃, TiO₂, ZrO₂, and Si₃N₄. Another possible substance is ZnO. Most of these oxides beneficially exhibit optical transparency, making them attractive for electronic displays, photovoltaic cells, and other optoelectronic devices, wherein visible light must either exit or enter the device during normal operation. The nitrides of Si and Al are also transparent in the visible spectrum. The term “visible light” as used herein includes electromagnetic radiation having a wavelength that falls in the infrared and ultraviolet spectral regions, as well as wavelengths generally perceptible to the human eye, all being within the operational limits of typical optoelectronic devices.

The precursors useful in ALD processes include those tabulated in published references such as M. Leskela and M. Ritala, “ALD precursor chemistry: Evolution and future challenges,” in Journal de Physique IV, vol. 9, pp. 837-852 (1999) and references therein.

In a representative embodiment, the ALD process can be accomplished using a two-step deposition that is repetitively carried out at a surface to build up a layer of the desired ALD material. Conceptually, the deposition reaction can be represented using the following schematic steps:

(A) SOH*+MRₓ→SOMRₓ₋₁*+RH (1)

(B) SOMR*+H₂O→SOMOH*+RH (2)

wherein S indicates the existing surface at each step, R is an organic group, M is a metal atom, and the asterisk “*” indicates a surface species.

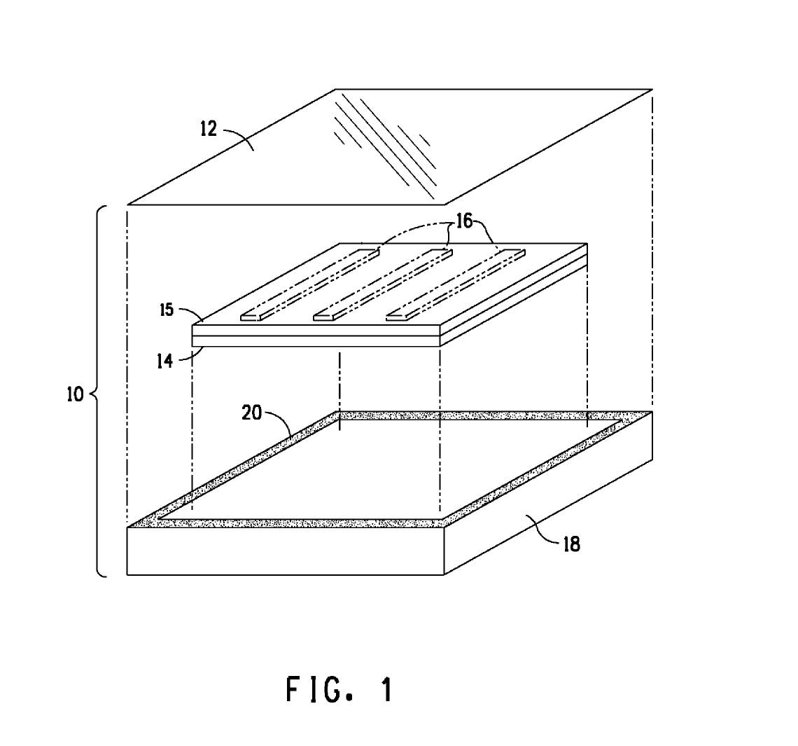

In one exemplary embodiment of this reaction scheme, aluminum oxide (alumina) may be formed by using trimethylaluminum (TMA) and water vapor in alternation as the film precursor and reactant, as illustrated schematically in FIGS. 1A to 1D. TMA reacts with native surface hydroxyls pendant on a substrate, as shown in FIG. 1A, to form Al—O linkages. A free methane molecule is formed for each linkage produced (FIG. 1B). The next exposure to water (or, alternatively, another oxidant such as ozone) (FIG. 1C) displaces the methyl groups remaining from the TMA, leaving pendant hydroxyls. The reaction sequence then continues with another TMA exposure (FIG. 1D). Further continuation of the sequence results in an alumina film of selectable thickness. Of course, the ALD process may be carried out with other precursors and reactants.

Layers of alumina as thin as 25 nm or less produced by ALD have been shown to provide an effective permeation barrier that can inhibit transmission of oxygen and water below the limits of detectability of conventional instrumentation. For example, US Patent Publication US200810182101 to Carcia et al. provides a 25 nm-thick aluminum oxide film on PEN that has an oxygen transmission rate of below 0.005 cc-O₂/m²/day.

As noted above, thin films deposited by previous CVD and PVD methods typically have microstructural growth features that permit facile gas permeation. In contrast, ALD can produce very thin films with extremely low gas permeability, making such films attractive as barrier layers for protecting sensitive electronic devices, including PV cells, organic light emitting devices (OLEDs), and other optoelectronic devices that are sensitive to the intrusion of moisture and/or oxygen. The ALD deposition occurs by a surface reaction that proceeds layer-by-layer, so it is inherently self-limiting and produces a highly conformal coating. The ALD layer can be formed either directly on a device itself or on a substrate, possibly flexible, that is thereafter affixed to a device or its mounting. This allows a wide range of devices, including those with complex topographies, to be fully coated and protected. In an embodiment, films produced by ALD are amorphous and exhibit a featureless microstructure. For example, a preferred ALD process provides for a non-directional, layer-by-layer growth mechanism to achieve a featureless microstructure and avoids columnar growth. It is found that columnar growth typically results in a granular microstructure that has grain boundaries that provide facile pathways for diffusion and may compromise initial gas permeation resistance.

However, it has been found that the attractive initial permeation resistance exhibited by ALD barrier films is, in some instances, compromised after exposure to conditions that simulate what a working device having an exposed ALD barrier film would encounter during its lifetime. For example, it is believed that alumina-based ALD films can be attacked by ambient moisture, resulting in an undesirable loss of barrier efficacy.

Accelerated aging testing of barrier materials is often carried out by exposing the material (or a device protected therewith) to elevated levels of heat and humidity. Frequently, 85° C. at 85% relative humidity (RH) is specified. It is regarded that testing under such accelerated aging conditions, although harsher than any actual condition the device is likely to see during its life cycle, provides a useful indicator of likely long-term performance stability. Devices are frequently specified as requiring satisfactory performance under the 85° C./85% RH condition for at least 1000 h.

In the present instance, it has been found that alumina films deposited by ALD initially exhibit excellent resistance to permeation of oxygen and water vapor. Upon exposure to 85° C./85% RH, the permeation resistance is maintained initially, but thereafter a degradation of the resistance begins. Surprisingly, the application of a suitable acrylic clear coating, e.g. a polymeric coating of a type used in automotive applications, is found to delay the onset of the degradation.

In various embodiments, the provision of a polymeric clear coat layer atop the ALD layer in the present barrier coating and barrier structure may provide one or more of: improving the long-term durability of the barrier properties; protecting the ALD layer from physical damage during subsequent processing, especially during the handling needed for continuous, in-line processing; and providing additional resistance to the effects of environmental exposure, e.g. during the lifetime of a photovoltaic device protected by the ALD layer, since such a device is necessarily deployed outdoors and thus exposed to the elements.

In an embodiment, an isocyanate- or melamine-crosslinked, acrylic clear coating beneficially forms an adherent protective layer on an ALD-applied oxide layer. Although not being bound by any theory, it is believed that chemical bonds can be formed between pendant surface hydroxyls and isocyanate or melamine functionality present in at least one of the components of a polymeric coating material.

In another embodiment, the present barrier coating and barrier structure can also be constructed with the oxide or nitride ALD layer being replaced with a layer comprising an alloy of an inorganic substance and a metalcone that are polymerically linked, such as that described in copending U.S. patent application Ser. No. 13/523,414 to Carcia et al., entitled “Gas Permeation Barrier Material” and incorporated herein by reference. As used herein, the term “metalcone” refers to a hybrid organic-inorganic, metal alkoxide polymer. Such a material can be formed using any suitable process, including a molecular layer deposition process that entails the reaction of a multifunctional inorganic monomer with a homo- or hetero-multifunctional organic monomer.

In still another embodiment, the oxide or nitride ALD layer is replaced by a multi-layer structure comprising sublayers of an ALD oxide or nitride and a metalcone. In some embodiments, these alloy or multilayer structures also benefit from the provision of an acrylic clear coat protective layer.

The protective acrylic polymer material used in the present barrier coating can have a weight average molecular weight (Mw) of about 3,000 to 100,000, and a glass transition temperature (Tg) in a range of from −40° C. to 80° C. and contain functional groups or pendant moieties that are reactive with isocyanate or other crosslinking functional groups, such as, for example, hydroxyl, amino, amide, glycidyl, silane and carboxyl groups. The acrylic polymer can have Mw in a range of from 3,000 to 100,000 in one embodiment, in a range of from 5,000 to 80,000 in another embodiment, in a range of from 8,000 to 50,000 in yet another embodiment. Tg of the acrylic polymer can range from −40° C. to 80° C. in one embodiment, −40° C. to 5° C. in another embodiment, 5° C. to 80° C. in yet another embodiment. The Tg of the acrylic polymer can be measured experimentally or calculated according to the Fox Equation. These acrylic polymers can be straight chain polymers, branched polymers, block copolymers, graft polymers, graft terpolymers or core shell polymers.

The acrylic polymers can be polymerized from a plurality of monomers, such as acrylates, methacrylates or derivatives thereof.

Suitable monomers can include, without limitation, linear alkyl(meth)acrylates having 1 to 12 carbon atoms in the alkyl group, cyclic or branched alkyl (meth)acrylates having 3 to 12 carbon atoms in the alkyl group, including isobornyl (meth)acrylate, styrene, alpha methyl styrene, vinyl toluene, (meth)acrylonitrile, (meth)acryl amides and monomers that provide crosslinkable functional groups, such as hydroxy alkyl (meth)acrylates having 1 to 4 carbon atoms in the alkyl group, glycidyl (meth)acrylate, amino alkyl (meth)acrylates having 1 to 4 carbon atoms in the alkyl group, (meth)acrylic acid, and alkoxy silyl alkyl (meth)acrylates, such as trimethoxysilylpropyl (meth)acrylate. Particularly, monomers having inherent low Tg properties can be suitable for deriving low Tg acrylic polymers when desired. Examples of low Tg monomers include butyl acrylate (Tg about −54° C.), 2-ethylhexyl acrylate (Tg about −50° C.), ethyl acrylate (Tg about −24° C.), isobutyl acrylate (Tg about −24° C.), and 2-ethylhexyl methacrylate (Tg about −10° C.). Monomers having inherent high Tg properties can be suitable for deriving high Tg acrylic polymers when desired. Examples of such high Tg monomers can include styrene (Tg: 100° C.), methyl methacrylate (MMA) (Tg: about 105° C.), isobornyl methacrylate (IBOMA) (Tg: about 165° C.), isobornyl acrylate (IBOA) (Tg: about 94° C.), cyclohexyl methacrylate (CHMA) (Tg: about 83° C.), and isobutyl methacrylate (IBMA) (Tg: about 55° C.). The abovementioned Tg values are derived from published literatures and are commonly accepted in the industry. Theoretical Tg's of the acrylic polymers can be predicted using the Fox equation based on Tg's of the monomers. Actual Tg's of the finished polymers can be measured by DSC (Differential Scanning calorimetry), in accordance with ASTM D3418 or E1356.

Suitable exemplary monomers can also include, without limitation, hydroxyalkyl esters of alpha,beta-olefinically unsaturated monocarboxylic acids with primary or secondary hydroxyl groups. These may, for example, comprise the hydroxyalkyl esters of acrylic acid, methacrylic acid, crotonic acid and/or isocrotonic acid. Examples of suitable hydroxyalkyl esters of alpha,beta-olefinically unsaturated monocarboxylic acids with primary hydroxyl groups can include hydroxyethyl (meth)acrylate, hydroxypropyl (meth)acrylate, hydroxybutyl (meth)acrylate, hydroxyamyl (meth)acrylate, hydroxyhexyl (meth)acrylate. Examples of suitable hydroxyalkyl esters with secondary hydroxyl groups can include 2-hydroxypropyl (meth)acrylate, 2-hydroxybutyl (meth)acrylate, 3-hydroxybutyl (meth)acrylate. Low Tg monomers, containing hydroxyl functional groups, such as 2-hydroxyethyl acrylate (Tg: −15° C.) and hydroxypropyl acylate (Tg: −7° C.) can be useful in decreasing Tg of the acrylic polymer to produce low Tg acrylic polymers and providing the crosslinkable functional groups. When high Tg acrylic polymers are desired, one or more high Tg monomers can be included. Examples of such high Tg hydroxyl monomers can include hydroxyethyl methacrylate (HEMA) (Tg: about 55° C.) and hydroxypropyl methacrylate (HPMA) (Tg: about 76° C.).

Suitable monomers can also include, without limitation, monomers that are reaction products of alpha,beta-unsaturated monocarboxylic acids with glycidyl esters of saturated monocarboxylic acids branched in alpha position, for example with glycidyl esters of saturated alpha-alkylalkanemonocarboxylic acids or alpha,alpha′-dialkylalkanemonocarboxylic acids. These can comprise the reaction products of (meth)acrylic acid with glycidyl esters of saturated alpha,alpha-dialkylalkanemonocarboxylic acids with 7 to 13 carbon atoms per molecule, particularly preferably with 9 to 11 carbon atoms per molecule. These reaction products can be formed before, during or after copolymerization reaction of the acrylic polymer.

Suitable monomers can further include, without limitation, monomers that are reaction products of hydroxyalkyl (meth)acrylates with lactones. Hydroxyalkyl (meth)acrylates which can be used include, for example, those stated above. Suitable lactones can include, for example, those that have 3 to 9 carbon atoms in the ring, wherein the rings can also comprise different substituents. Examples of lactones can include gamma-butyrolactone, delta-valerolactone, epsilon-caprolactone, beta-hydroxy-beta-methyl-delta-valerolactone, lambda-laurolactone or a mixture thereof. In one example, the reaction products can comprise those prepared from 1 mole of a hydroxyalkyl ester of an alpha,beta-unsaturated monocarboxylic acid and 1 to 5 moles, preferably on average 2 moles, of a lactone. The hydroxyl groups of the hydroxyalkyl esters can be modified with the lactone before, during or after the copolymerization reaction.

Suitable monomers can also include, without limitation, unsaturated monomers such as, for example, allyl glycidyl ether, 3,4-epoxy-1-vinylcyclohexane, epoxycyclohexyl (meth)acrylate, vinyl glycidyl ether and glycidyl (meth)acrylate, that can be used to provide the acrylic polymer with glycidyl groups. In one example, glycidyl (meth)acrylate can be used.

Suitable monomers can also include, without limitation, monomers that are free-radically polymerizable, olefinically unsaturated monomers which, apart from at least one olefinic double bond, do not contain additional functional groups. Such monomers include, for example, esters of olefinically unsaturated carboxylic acids with aliphatic monohydric branched or unbranched as well as cyclic alcohols with 1 to 20 carbon atoms. Examples of the unsaturated carboxylic acids can include acrylic acid, methacrylic acid, crotonic acid and isocrotonic acid. In one embodiment, esters of (meth)acrylic acid can be used. Examples of esters of (meth)acrylic acid can include methyl acrylate, ethyl acrylate, isopropyl acrylate, tert.-butyl acrylate, n-butyl acrylate, isobutyl acrylate, 2-ethylhexyl acrylate, lauryl acrylate, stearyl acrylate and the corresponding methacrylates. Examples of esters of (meth)acrylic acid with cyclic alcohols can include cyclohexyl acrylate, trimethylcyclohexyl acrylate, 4-tert.-butylcyclohexyl acrylate, isobornyl acrylate and the corresponding methacrylates.

Suitable monomers can also include, without limitation, unsaturated monomers that do not contain additional functional groups for example, vinyl ethers, such as isobutyl vinyl ether and vinyl esters, such as vinyl acetate, vinyl propionate, vinyl aromatic hydrocarbons, preferably those with 8 to 9 carbon atoms per molecule. Examples of such monomers can include styrene, alpha-methylstyrene, chlorostyrenes, 2,5-dimethylstyrene, p-methoxystyrene, vinyl toluene. In one embodiment, styrene can be used.

Suitable monomers can also include, without limitation, small proportions of olefinically polyunsaturated monomers. These olefinically polyunsaturated monomers are monomers having at least 2 free-radically polymerizable double bonds per molecule. Examples of these olefinically polyunsaturated monomers can include divinylbenzene, 1,4-butanediol diacrylate, 1,6-hexanediol diacrylate, neopentyl glycol dimethacrylate, and glycerol dimethacrylate.

The acrylic polymers employed in the practice of this disclosure can generally be polymerized by free-radical copolymerization using conventional processes well known to those skilled in the art, for example, bulk, solution or bead polymerization, in particular by free-radical solution polymerization using free-radical initiators.

The crosslinking agents that are suitable for the protective coating composition used in the practice of this disclosure include compounds having crosslinking functional groups. Examples of such compounds can be organic polyisocyanates. Examples of organic polyisocyanates include aliphatic polyisocyanates, cycloaliphatic polyisocyanates, aromatic polyisocyanates and isocyanate adducts.

Examples of suitable aliphatic, cycloaliphatic and aromatic polyisocyanates that can be used include, without limitation, the following: 2,4-toluene diisocyanate, 2,6-toluene diisocyanate (“TDI”), 4,4-diphenylmethane diisocyanate (“MDI”), 4,4′-dicyclohexyl methane diisocyanate (“H12MDI”), 3,3′-dimethyl-4,4′-biphenyl diisocyanate (“TODI”), 1,4-benzene diisocyanate, trans-cyclohexane-1,4-diisocyanate, 1,5-naphthalene diisocyanate (“NDI”), 1,6-hexamethylene diisocyanate (“HDI”), 4,6-xylene diisocyanate, isophorone diisocyanate,(“IPDI”), other aliphatic or cycloaliphatic di-, tri- or tetra-isocyanates, such as 1,2-propylene diisocyanate, tetramethylene diisocyanate, 2,3-butylene diisocyanate, octamethylene diisocyanate, 2,2,4-trimethyl hexamethylene diisocyanate, dodecamethylene diisocyanate, omega-dipropyl ether diisocyanate, 1,3-cyclopentane diisocyanate, 1,2-cyclohexane diisocyanate, 1,4-cyclohexane diisocyanate, 4-methyl-1,3-diisocyanatocyclohexane, dicyclohexylmethane-4,4′-diisocyanate, 3,3′-dimethyl-dicyclohexylmethane 4,4′-diisocyanate, polyisocyanates having isocyanurate structural units, such as the isocyanurate of hexamethylene diisocyanate and the isocyanurate of isophorone diisocyanate, the adduct of 2 molecules of a diisocyanate, such as hexamethylene diisocyanate, uretidiones of hexamethylene diisocyanate, uretidiones of isophorone diisocyanate and a diol, such as ethylene glycol, the adduct of 3 molecules of hexamethylene diisocyanate and 1 molecule of water, allophanates, trimers and biurets, for example, of hexamethylene diisocyanate, allophanates, trimers and biurets, for example, of isophorone diisocyanate and the isocyanurate of hexane diisocyanate. MDI, HDI, TDI and isophorone diisocyanate are preferred because of their commercial availability.

Tri-functional isocyanates also can be used, such as triphenyl methane triisocyanate, 1,3,5-benzene triisocyanate, 2,4,6-toluene triisocyanate. Trimers of diisocyanates, such as the trimer of hexamethylene diisocyanate, sold as Desmodur® N 3300A from Bayer MaterialScience and the trimer of isophorone diisocyanate are also suitable.

An isocyanate functional adduct can be used, such as an adduct of an aliphatic polyisocyanate and a polyol or an adduct of an aliphatic polyisocyanate and an amine. Also, any of the aforementioned polyisocyanates can be used with a polyol to form an adduct. Polyols, such as trimethylol alkanes, particularly, trimethylol propane or ethane can be used to form an adduct.

The protective polymeric coating material used in fabricating the present barrier coating can comprise one or more solvents. Typically the polymeric coating material can comprise up to 80% by weight, of one or more solvents. Typically, the coating material herein can have, in various embodiments, a solids content in a range of from 20% to 80% by weight, or from 50% to 80% by weight, or from 60% to 80% by weight, all based on the total weight of the polymeric coating material. The coating material herein can also be formulated at 100% solids by using a low molecular weight acrylic resin reactive diluent known to those skilled in the art.

Any typical organic solvents can be incorporated in the protective polymeric coating composition used herein. Examples of solvents can include, but not limited to, aromatic hydrocarbons, such as toluene and xylene; ketones, such as acetone, methyl ethyl ketone, methyl isobutyl ketone, methyl amyl ketone, and diisobutyl ketone; esters, such as ethyl acetate, n-butyl acetate, and isobutyl acetate; and combinations thereof.

The present protective coating composition can also comprise one or more ultraviolet light stabilizers in the amount of 0.1% to 10% by weight, based on the weight of the binder. Examples of such ultraviolet light stabilizers can include ultraviolet light absorbers, screeners, quenchers, and hindered amine light stabilizers. An antioxidant can also be added to the coating composition, in the amount of about 0.1% to 5% by weight, based on the weight of the binder.

Typical ultraviolet light stabilizers that are suitable for the present protective coating material include, without limitation, benzophenones, triazoles, triazines, benzoates, hindered amines and mixtures thereof. A blend of hindered amine light stabilizers, such as Tinuvin® 328 and Tinuvin® 292, all commercially available from BASF, Ludwigshaven, Germany, under respective registered trademarks, can be used.

Useful ultraviolet light absorbers include, without limitation, hydroxyphenyl benzotriazoles, such as 2-(2-hydroxy-5-methylphenyl)-2H-benzotrazole, 2-(2-hydroxy-3,5-di-tert.amyl-phenyl)-2H-benzotriazole, 2-[2-hydroxy-3,5-di(1,1-dimethylbenzyl)phenyl]-2H-benzotriazole, reaction product of 2-(2-hydroxy-3-tert.butyl-5-methyl propionate)-2H-benzotriazole and polyethylene ether glycol having a weight average molecular weight of 300, 2-(2-hydroxy-3-tert.butyl-5-iso-octyl propionate)-2H-benzotriazole; hydroxyphenyl s-triazines, such as 2-(4((2,-hydroxy-3-dodecyloxy/tridecyloxypropyl)-oxy)-2-hydroxyphenyl]-4,6-bis(2,4-dimethylphenyl)-1,3,5-triazine, 2-(4(2-hydroxy-3-(2-ethylhexyl)-oxy)-2-hydroxyphenyl]-4,6-bis(2,4-dimethylphenyl)1,3,5-triazine, 2-(4-octyloxy-2-hydroxyphenyl)-4,6-bis(2,4-dimethylphenyl)-1,3,5-triazine; hydroxybenzophenone U.V. absorbers, such as 2,4-dihydroxybenzophenone, 2-hydroxy-4-octyloxybenzophenone, and 2-hydroxy-4-dodecyloxybenzophenone.

Typical hindered amine light stabilizers can include, without limitation, N-(1,2,2,6,6-pentamethyl-4-piperidinyl)-2-dodecyl succinimide, N(1 acetyl-2,2,6,6-tetramethyl-4-piperidinyl)-2-dodecyl succinimide, N-(2hydroxyethyl)-2,6,6,6-tetramethylpiperidine-4-ol-succinic acid copolymer, 1,3,5 triazine-2,4,6-triamine, N,N′″-[1,2-ethanediybis[[[4,6-bis[butyl(1,2,2,6,6-pentamethyl-4-piperidinyl)amino]-1,3,5-triazine-2-yl]imino]-3,1-propanediyl]]bis[N,N′″-dibutyl-N′,N′″-bis(1,2,2,6,6-pentamethyl-4-piperidinyl)], poly[[6-[1,1,3,3-tetramethylbutyl)-amino]-1,3,5-trianzine-2,4-diyl][2,2,6,6-tetramethylpiperidinyl)-imino]-1,6-hexane-diyl[(2,2,6,6-tetramethyl-4-piperidinyl)-imino]), bis(2,2,6,6-tetramethyl-4-piperidinyl)sebacate, bis(1,2,2,6,6-pentamethyl-4-piperidinyl)sebacate, bis(1-octyloxy-2,2,6,6-tetramethyl-4-piperidinyl)sebacate, bis(1,2,2,6,6-pentamethyl-4-piperidinyl)[3,5bis(1,1-dimethylethyl-4-hydroxy-phenyl)methyl]butyl propanedioate, 8-acetyl-3-dodecyl-7,7,9,9,-tetramethyl-1,3,8-triazaspiro(4,5)decane-2,4-dione, and dodecyl/tetradecyl-3-(2,2,4,4-tetramethyl-2l-oxo-7-oxa-3,20-diazal dispiro(5.1.11.2)henicosan-20-yl)propionate.

Typical antioxidants that useful in the present protective polymeric coating can include, without limitation, tetrakis[methylene(3,5-di-tert-butylhydroxy hydrocinnamate)]methane, octadecyl 3,5-di-tert-butyl-4-hydroxyhydrocinnamate, tris(2,4-di-tert-butylphenyl) phosphite, 1,3,5-tris(3,5-di-tert-butyl-4-hydroxybenzyl)-1,3,5-triazine-2,4,6(1H,3H,5H)-trione and benzenepropanoic acid, 3,5-bis(1,1-dimethyl-ethyl)-4-hydroxy-C7-C9 branched alkyl esters. Typically useful antioxidants can also include hydroperoxide decomposers, such as Sanko® HCA (9,10-dihydro-9-oxa-10-phosphenanthrene-10-oxide), triphenyl phosphate and other organo-phosphorous compounds, such as Irgafos® TNPP, Irgafos® 168, Irgafos® 12, Irgafos® 38, and Irgafos® P-EPQ from BASF; Ultranox® 626, Ultranox® 641, and Weston 618 from GE Specialty Chemicals; Mark PEP-6 and Mark HP-10 from Asahi Denka; Ethanox 398 from Albemarle; and Doverphos® S-9228 from Dover Chemicals.

The protective polymeric coating compositions herein can comprise conventional coating additives. Examples of such additives can include wetting agents, leveling and flow control agents, for example, Resiflow®S (polybutylacrylate), BYK® 358 (high molecular weight polyacrylates), BYK® 333 (polyether-modified siloxane); leveling agents based on (meth)acrylic homopolymers; rheological control agents, such as highly disperse silica, or fumed silica; thickeners, such as partially crosslinked polycarboxylic acid or polyurethanes; and antifoaming agents. The additives are used in conventional amounts familiar to those skilled in the art.

The present coating compositions can further contain reactive low molecular weight compounds as reactive diluents that are capable of reacting with the crosslinking agent. For example, low molecular weight polyhydroxyl compounds, such as ethylene glycol, propylene glycol, trimethylolpropane and 1,6-dihydroxyhexane can be used.

In a typical two-pack coating composition, the two packages are mixed together shortly before application. The first package typically can contain the binder, including one or more polymers having one or more hydroxyl crosslinkable functional groups, additives, and solvents. The second package can contain the crosslinking agent, such as a polyisocyanate crosslinking agent, and solvents.

Curing of the coating composition can be accomplished at ambient temperatures, such as temperatures in a range of from 18° C. to 35° C., or at elevated temperatures, such as at temperatures in a range of from 35° C. to 150° C. Typical curing temperatures of 20° C. to 80° C., in particular of 20° C. to 60° C., also can be used.

The protective coating composition can be applied by conventional techniques, such as spraying, electrostatic spraying, dipping, brushing, and flow coating. Typically, the coating can be applied to a substrate to form a sag-free coating layer having a wet coating thickness, also known as wet film thickness (wft), in a range of, in one example from 1 to 8 mils (about 25 to 200 μm), in another example from 2 to 8 mils (about 50 to 200 μm). After curing and drying, dry coating thickness can be typically in a range of from 0.5 to 4 mils (about 12 to 100 μm), or 0.5 to 1.5 mils (about 12 to 40 μm), or about 1 to 4 mils (about 25 to 100 μm).

### EXAMPLES

The operation and effects of certain embodiments of the present disclosure may be more fully appreciated from Examples 1-4 and Comparative Examples 1-2 described below. The embodiments on which these examples are based are representative only, and the selection of those embodiments to illustrate aspects of the invention does not indicate that materials, components, reactants, conditions, techniques and/or configurations not described in the examples are not suitable for use herein, or that subject matter not described in the examples is excluded from the scope of the appended claims and equivalents thereof.

### Example 1

An atomic layer deposition (ALD) process is used to produce a nominally 25 nm thick coating of aluminum oxide (Al₂O₃) (275 ALD cycles at a growth rate averaging 0.09 nm per cycle) on 5 mil (˜125 μm) thick PET film substrate (DuPont-Tejin product code XST6578). The ALD process is carried out in a chamber that can be evacuated and back-filled with the reactant gases. Each ALD cycle entails first an exposure to trimethyl aluminum and second an exposure to water, with the substrate being held at 100° C.

After deposition of the 25 nm alumina layer, pieces of the coated PET film (350 mm wide×2 m long) are attached with binder clips to rigid aluminum backing panels for subsequent processing.

A clear-coat material is prepared by combining: (1) a first component that is a mixture of polyester and acrylic resins containing methylmethacrylate (MMA) and hydroxyethylmethacrylate (HEMA) functionality carried in a solvent mixture of butyl acetate, acetone, methylethylketone, and methylisobutylketone; (2) a second activator component that is a trifunctional aliphatic isocyanate resin carried in a solvent mixture of butyl acetate, acetone, methylethylketone, and methylisobutylketone; and (3) a solvent mixture of butyl acetate, 4,6-Dimethyl-2-heptanone, acetone, methylethylketone, and methylisobutylketone. These components are mixed thoroughly at a ratio of 3:1:1 by volume to obtain a coating material with a viscosity suitable for spray application.

The mixed material is then placed in a Sata 3000RP spray gun (DAN-AM Co., Spring Valley, Minn. 55975). The gun is operated at 30-35 psi pressure with a 1.3 mm diameter tip and the fan fully open to apply a coating approximately 1 mil (25 μm thick). The backing-panel with film attached is then cured in an oven at 70° C. for 20 minutes.

Thereafter, the coated and cured ALD-PET film is laminated to a 2 mil (50 μm) thick TEFLON® FEP film (available from DuPont Corporation, Circleville, Ohio) pre-coated with 2 mil (50 μm) thick pressure sensitive adhesive using a nip roll laminator (AGL4400, Advanced Greig Laminators, Wis.) operated at room temperature with a feed rate of 2.8 cm/s and a pressure of 170 kPa between the two rubber-coated nip rolls. The final laminated film (2 m by 350 mm) containing the following layers—2 mil FEP/2 mil adhesive/1 mil acrylic coating/25 nm alumina/5 mil PET—is then rolled onto a 15 cm diameter plastic core.

### Comparative Example A

Comparative Example A is fabricated using the same ALD coating process and the same laminating technique used for Example 1, thereby to produce a sample of alumina-coated PET laminated to an FEP substrate, but without the acrylic spray coating.

### Example 2

A test structure is formed to determine the long-term stability of the acrylic-coated gas permeation barrier structure against environmental exposure, using cobalt chloride moisture test strips vacuum-laminated in a sandwich-like structure that simulates a photovoltaic module. As is known in the art, the test strips undergo a color change when exposed to moisture, based on the hydration of CoCl₂, which is blue in its anhydrous form and pink or red when fully hydrated. The use of cobalt chloride test strips to monitor moisture penetration is recognized, e.g. in M. Otsuka, S. Yoshida, C. Okawara, T. Hachisuka, and T. Matsui, “Study of Transparent High Gas Barrier Film and the Evaluation of Water Vapor Transmission Rate (WVTR)”; Society of Vacuum Coaters 51st Annual Technical Conference Proceedings (2008), p. 814, which is incorporated herein by reference.

As depicted in FIG. 1, a test structure 10 is formed on a 10 cm×10 cm square back sheet 18 of 3 mm thick glass. A frame 20 of butyl based edge seal tape forms a perimeter on the back sheet's face. A bottom layer 14 of ethylene copolymer-based ionomer encapsulant (DuPont PV5400) is placed within the square formed by the edge seal square 20. Three strips of CoCl₂-impregnated moisture test paper 16 (6 mm wide by 5 cm long) are laid on encapsulant 14. Bottom layer 14 and test papers 16 are then covered with a top encapsulant layer 15 of the same ionomer material. The stack is completed by placing a 10 cm×10 cm piece 12 of the acrylic-coated ALD/PET material prepared in Example 1 atop the other layers.

Thereafter, the stacked individual layers are vacuum-laminated using a Meier vacuum laminator. The stack is placed on the laminator platen and the laminator is operated according to the following sequence:

Set Temperature of platen=150° C.
Stage 1-17 min evacuation (chamber=0 mbar, cover=1 mbar)
Stage 2-5 min pressing (chamber=0 mbar, cover=400 mbar)
Stage 3-5 min crosslinking/heating (chamber=0 mbar, cover=400 mbar)
Stage 4-30 seconds ventilation
Stage 5-30 seconds open cover

A thermocouple is used to continuously monitor temperature, and it is found that the internal temperature of the edge seal material 20 reaches 130° C. by the end of Stage 1.

### Comparative Example B

The same experimental method used to create the test structure of Example 2 was used to create a test structure for Comparative Example B, except that the uncoated ALD/PET sheet of Comparative Example A is used instead of acrylic-coated ALD/PET sheet.

### Example 3

The test structures of Example 2 and Comparative Example B are tested to determine the improvement in persistence of gas permeation resistance that results from the application of an acrylic clear coating of an ALD barrier layer. Both test structures are exposed to damp heat (85° C./85% relative humidity) for extended times, with the permeation of moisture being indicated by color changes in the CoCl₂ test strips from red toward blue.

The color change is determined by an automated colorimetric technique. For each test point, a digitized, scanned image of the test structure is acquired using an Epson EXPRESSION 10000XL Graphic Art Model flat-bed scanner driven by a personal computer, with the scanning software set to deliver a file in TIFF format without any color correction or brightness adjustment. A standard grey-scale card is also included in each scan to detect, and permit correction for, any overall drift in the scanner light over time. The color evolution is determined by comparing images before any damp heat exposure (termed t=0) to images taken at regular intervals after the environmental exposure (t=tᵢ, with i=1, 2, . . . ). The evolution is expressed as semi-quantitative measure (here termed ΔE) determined as follows.

Each image is first converted from an RGB representation to an L*a*b* representation using Adobe Photoshop® software in accordance with the CIE protocol. The image is then cropped to include only the area occupied by the test strips, with a margin taken inward to avoid artifacts at the strip edges. Each image is split into separate L*, a*, and b* channels and an average 8-bit grey level is calculated for each. These grey levels are then converted to L* values (0 to 100) and a* and b* values (−60 to +60). The value of ΔE at each tᵢ is calculated from the values L₀*, a₀*, and b₀* at t=0 and Lᵢ*, aᵢ*, and bᵢ* at t=tᵢ using the formula:

ΔE=\sqrt{(L₀*−L₁*)²+(a₀*−a₁*)²+(b₀*−b₁*)²}

The intrusion of water vapor signaled in the ΔE testing protocol provides a semiquantitative measure of the actual rate of water vapor permeation through the present barrier structure. It is determined that a ΔE is 10 or less after 1000 h (˜42 days) under given conditions corresponds to a water vapor permeation rate of less than 3×10⁻⁴ g-H₂O/m² day.

Data are collected using 4 test structures made using Example 1 coated ALD/PET (labeled Ex1-01 through Ex1-04) and 8 test structures made using Comparative Example A uncoated ALD/PET (labeled CA-01 through CA-08) that are all exposed to continuous damp heat (85° C. and 85% relative humidity). The test structures are removed briefly every 7 days to measure the color change of the cobalt chloride strips.

As seen in the Table 1 data, the Comparative Example A—based samples all quickly change color, producing a ΔE=10 value within 24 days (574 hours) of damp heat exposure. This amount of color change (ΔE=10) for CoCl₂ test strips that are embedded in actual CIGS based PV modules are correlated to a moisture induced drop off in efficiency of the module by following both test strip color change and actual electrical performance of the module.

In contrast, the data in Table I for the Example 1-based structures show a greatly enhanced moisture barrier performance, relative to Comparative Example A samples, as the ΔE values remain below 10, even after 126 days (3024 hours) of damp heat exposure.

TABLE I
ΔE Color Change of Test Strips at Various Damp Heat Exposure Times

| No. | CA- | CA- | CA- | CA- | CA- | CA- | CA- | CA- | Ex1- | Ex1- | Ex1- | Ex1- |
|---|---|---|---|---|---|---|---|---|---|---|---|---|
| Days | 01 | 02 | 03 | 04 | 05 | 06 | 07 | 08 | 01 | 02 | 03 | 04 |
| 0 | 0.0 | 0.0 | 0.0 | 0.0 | 0.0 | 0.0 | 0.0 | 0.0 | 0.0 | 0.0 | 0.0 | 0.0 |
| 7 | 1.1 | 1.1 | 1.2 | 0.9 | 1.8 | 1.1 | 1.4 | 1.1 | 1.4 | 1.3 | 1.5 | 1.3 |
| 14 | 4.0 | 4.1 | 5.3 | 3.6 | 5.1 | 4.2 | 6.8 | 5.0 | 1.8 | 1.6 | 1.9 | 1.7 |
| 21 | 10.6 | 10.6 | 12.0 | 9.7 | 11.9 | 10.7 | 13.7 | 11.6 | 2.2 | 2.0 | 2.3 | 2.1 |
| 28 | | | | | | | | | 3.0 | 2.7 | 3.0 | 2.8 |
| 35 | | | | | | | | | 3.6 | 3.3 | 3.6 | 3.4 |
| 41 | | | | | | | | | 3.7 | 3.3 | 3.7 | 3.6 |
| 49 | | | | | | | | | 4.5 | 4.2 | 4.5 | 4.2 |
| 57 | | | | | | | | | 5.4 | 5.0 | 5.3 | 5.1 |
| 65 | | | | | | | | | 6.0 | 5.6 | 5.8 | 5.6 |
| 72 | | | | | | | | | 6.5 | 6.1 | 6.3 | 6.0 |
| 77 | | | | | | | | | 6.6 | 6.2 | 6.4 | 6.0 |
| 84 | | | | | | | | | 7.2 | 6.7 | 6.9 | 6.5 |
| 97 | | | | | | | | | 7.7 | 7.2 | 7.4 | 6.9 |
| 105 | | | | | | | | | 8.2 | 7.8 | 8.0 | 7.3 |
| 112 | | | | | | | | | 8.7 | 8.4 | 8.5 | 7.8 |
| 119 | | | | | | | | | 9.2 | 8.8 | 8.9 | 8.1 |
| 126 | | | | | | | | | 9.7 | 9.3 | 9.4 | 8.6 |
| 133 | | | | | | | | | 11.2 | 10.8 | 11.0 | 9.9 |
| 140 | | | | | | | | | 11.4 | 11.1 | 11.2 | 10.1 |

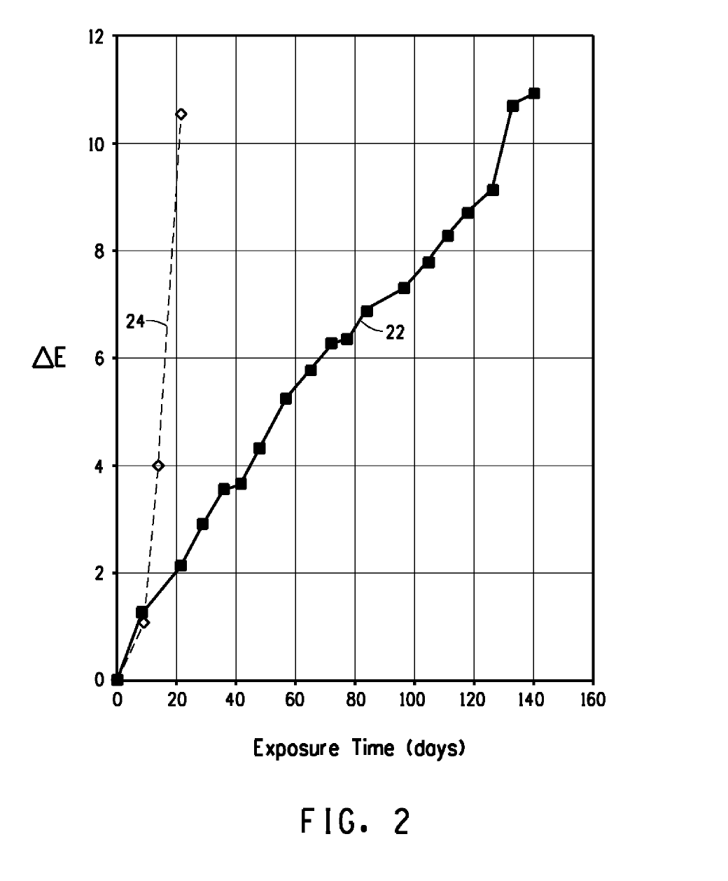

The data given in Table I are further shown in FIG. 2, which depicts the evolution of the properties with time of Samples EX1-01 through EX1-04 of Example 2 and Samples CA-01 through CA-08 of Comparative Example 2. At each time point, the numerical average of the values for Samples EX1-01 through EX1-04 (curve 22) and for Samples CA-01 through CA-08 (curve 24) is plotted. The presence of the acrylic clear coat in Samples EX1-01 through EX1-04 demonstrably retards the color change of the test strips.

The value of the ΔE color change for the present exemplary test structures remains below 10 for about 120 days (2880 h), indicating that the water vapor transmission rate of the structure is less than 3×10⁻⁴ g-H₂O/m² day when measured at 38° C. and 85% relative humidity.

### Example 4

Four test structures are produced as described above in Example 2 and using the Example 1 barrier structure. These test structures (labeled Ex1-05 through Ex1-08) are subjected to repeated exposures to a “Humidity/Freeze” testing protocol as described in IEC 61646, 2nd ed., 2008-05, “Thin-film terrestrial photovoltaic (PV) modules—Design qualification and type approval.”

Each cycle for the humidity/freeze test involves exposing test structure samples of the type used for Example 2, first to damp heat (85° C./85% relative humidity) for 20 h, then to cold (−40° C. with no humidity control) for 4 h. This 20 h/4 h cycle is repeated 10 times to complete one experiment. This test thermally stresses the interface between the clear coating and the 25 nm ALD alumina layer. Poor coatings are known to exhibit delamination from the alumina surface, leading to premature, moisture-induced color change of the cobalt chloride test strips.

Table II shows the color change data for samples that are subjected to 6 humidity/freeze experiments comprising a total of 60 temperature cycles (85° C. to −40° C.). All samples show a ΔE that remains less than 6 after the 60 cycles.

No visible evidence of delamination is noted in any of the samples.

TABLE II
ΔE Color Change of Test Strips after
Various Cycles of Humidity/Freeze Testing

| H/F Cycles | Ex1-05 | Ex1-06 | Ex1-07 | Ex1-08 |
|---|---|---|---|---|
| 0 | 0.0 | 0.0 | 0.0 | 0.0 |
| 1 | 1.6 | 1.5 | 1.6 | 1.7 |
| 2 | 1.8 | 1.6 | 1.8 | 1.9 |
| 3 | 2.9 | 2.7 | 3.0 | 3.1 |
| 4 | 3.7 | 3.4 | 3.9 | 3.9 |
| 5 | 4.4 | 4.2 | 4.6 | 4.7 |
| 6 | 4.8 | 4.7 | 5.1 | 5.2 |

Having thus described the invention in rather full detail, it will be understood that this detail need not be strictly adhered to but that further changes and modifications may suggest themselves to one skilled in the art, all falling within the scope of the invention as defined by the subjoined claims.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

In this specification, unless explicitly stated otherwise or indicated to the contrary by the context of usage,

(a) amounts, sizes, ranges, formulations, parameters, and other quantities and characteristics recited herein, particularly when modified by the term “about,” may but need not be exact, and may also be approximate and/or larger or smaller (as desired) than stated, reflecting tolerances, conversion factors, rounding off, measurement error, and the like, as well as the inclusion within a stated value of those values outside it that have, within the context of this invention, functional and/or operable equivalence to the stated value; and

(b) all numerical quantities of parts, percentage, or ratio are given as parts, percentage, or ratio by weight; the stated parts, percentage, or ratio by weight may or may not add up to 100.

What is claimed is:

1. A barrier structure, comprising, in sequence:
(a) a carrier substrate;
(b) an inorganic layer deposited on the carrier substrate and comprising an oxide or a nitride of an element selected from Groups IVB, VB, VIB, IIIA, IVA of the periodic table, the oxide or nitride having an amorphous and featureless microstructure; and
(c) a polymeric layer adhered to the inorganic layer and comprising a network wherein units of a crosslinkable component are linked to units of a crosslinking component.

2. The barrier structure of claim 1, wherein the carrier substrate is a flexible plastic sheet.

3. The barrier structure of claim 1, wherein at least one of the crosslinkable component and the crosslinking component includes isocyanate or melamine functionality.

4. The barrier structure of claim 1, wherein the inorganic layer has a thickness ranging from 2 nm to 100 nm.

5. The barrier structure of claim 1, wherein the inorganic layer has a total thickness of at most 25 nm and the structure is capable of maintaining a water vapor transmission rate of less than 0.0005 g-H₂O/m²-day after exposure at 85° C. to an atmosphere having a relative humidity of 85% for at least 1000 h, the water vapor transmission rate being measured at 38° C. and 85% relative humidity.

6. The barrier structure of claim 1, wherein the inorganic layer is an oxide.

7. The barrier structure of claim 1, wherein the inorganic layer is aluminum oxide.

8. The barrier structure of claim 1, wherein the inorganic layer comprises an adhesion layer interposed between the carrier substrate and the oxide or nitride.

9. The barrier structure of claim 1, wherein the inorganic layer is formed by atomic layer deposition.

10. An electronic device, comprising:
(a) a circuit element;
(b) a barrier coating comprising an inorganic layer and a polymeric layer disposed, in sequence, on the circuit element, and wherein:
(i) the inorganic layer comprises an oxide or a nitride of an element selected from Groups IVB, VB, VIB, IIIA, IVA of the periodic table, the oxide or nitride having an amorphous and featureless microstructure; and
(ii) the polymeric layer thereon comprises a network wherein units of a crosslinkable component are linked to units of a crosslinking component.

11. The electronic device of claim 10, wherein at least one of the crosslinkable component and the crosslinking component includes isocyanate or melamine functionality.

12. The electronic device of claim 10, wherein the barrier coating has a thickness ranging from 2 nm to 100 nm.

13. The electronic device of claim 10, wherein the barrier coating has a total thickness of at most 25 nm and is capable of maintaining a water vapor transmission rate of less than 0.0005 g-H₂O/m²-day after exposure at 85° C. to an atmosphere having a relative humidity of 85% for at least 1000 h, the water vapor transmission rate being measured at 38° C. and 85% relative humidity.

14. The electronic device of claim 10, wherein the barrier coating is disposed directly on the circuit element.

15. The electronic device of claim 10, wherein the inorganic layer comprises an adhesion layer interposed between the circuit element and the oxide or nitride.

16. The electronic device of claim 10, further comprising a first carrier substrate having opposing first and second major surfaces and wherein the barrier coating is disposed on at least the first major surface of the first carrier substrate and the carrier substrate is affixed to the circuit element.

17. A process for manufacturing a barrier coating comprising the steps of:
(a) providing a substrate having a major surface;
(b) depositing an inorganic layer on the substrate using an atomic layer deposition process, the inorganic layer comprising an oxide or a nitride of an element selected from Groups IVB, VB, VIB, IIIA, IVA of the periodic table, the oxide or nitride having an amorphous and featureless microstructure;
(c) thereafter applying on the inorganic layer a polymeric layer that comprises a network wherein units of a crosslinkable component are linked to units of a crosslinking component.

18. The process of claim 17, wherein at least one of the crosslinkable component and the crosslinking component includes isocyanate or melamine functionality.

19. The process of claim 17, wherein the substrate is a flexible polymer.

20. The process of claim 17, wherein the substrate is an electronic circuit device.
